(19) United States
(12) Patent Application Publication
(10) Pub. No.: US 2025/0145517 A1
(43) Pub. Date: May 8, 2025

(54) LOW-TEMPERATURE FIRED CERAMIC AND ELECTRONIC COMPONENT

(71) Applicant: Murata Manufacturing Co., Ltd., Nagaokakyo-shi (JP)

(72) Inventors: Sadaaki SAKAMOTO, Nagaokakyo-shi (JP); Yasutaka SUGIMOTO, Nagaokakyo-shi (JP); Satoru ADACHI, Nagaokakyo-Shi (JP)

(21) Appl. No.: 19/002,069

(22) Filed: Dec. 26, 2024

Related U.S. Application Data
(63) Continuation of application No. PCT/JP2023/023143, filed on Jun. 22, 2023.

(30) Foreign Application Priority Data
Jul. 1, 2022 (JP) 2022-107080

(51) Int. Cl. C03C 14/00

(52) U.S. Cl. CPC C03C 14/006; C03C 2214/16

(57) ABSTRACT

A low-temperature fired ceramic containing: a fired glass component that contains B₂O₃, SiO₂, and an alkaline earth metal oxide and excluding Li₂O, and a percentage of the alkaline earth metal oxide in the fired glass component is 10 mol % or less; and one or more oxides of ceramic crystalline components.

### CROSS REFERENCE TO RELATED APPLICATIONS

The present application is a continuation of International application No. PCT/JP2023/023143, filed Jun. 22, 2023, which claims priority to Japanese Patent Application No. 2022-107080, filed Jul. 1, 2022, the entire contents of each of which are incorporated herein by reference.

### TECHNICAL FIELD

The present disclosure relates to a low-temperature fired ceramic and an electronic component.

### BACKGROUND ART

Known ceramic materials for ceramic multilayer wiring boards include a glass ceramic material (LTCC material) that can be fired at a low temperature.

For example, JP 2004-26529 A (“Patent Literature 1”) discloses a glass composition for a low-temperature fired substrate having a basic composition represented by RO—Al₂O₃—B₂O₃—SiO₂ (RO is one or more selected from the group consisting of MgO, Cao, Sro, Bao, and ZnO), wherein RO and Al₂O₃ are each in the range of 1 to 25 mol %, and the molar percent ratio of SiO₂/B₂O₃ is 1.3 or less. Patent Literature 1 also discloses a glass ceramic containing a filler in the glass composition for a low-temperature fired substrate.

### SUMMARY OF THE DISCLOSURE

A reduction in dielectric loss of glass ceramics requires a reduction in amounts of an alkali metal oxide and an alkaline earth metal oxide in glass in the form of a fired body obtained by firing. Yet, in Patent Literature 1, the composition of the glass before firing is merely specified that RO is in the range of 25 mol % or less, and the composition of the fired body obtained by firing is nowhere specified. Thus, it is uncertain whether the dielectric loss can always be reduced.

One of the reasons why the specification given in Patent Literature 1 is insufficient to reduce the dielectric loss is that crystals containing an alkaline earth metal oxide may precipitate from the glass during firing. In this case, the amount of the alkaline earth metal oxide in the glass in the form of a fired body is smaller than the amount of the alkaline earth metal oxide in the glass before firing.

Another reason is that an alkaline earth metal oxide (e.g., Ba₂Ti₉O₂₀), which is usually contained in a ceramic to be mixed with glass before firing, may dissolve into the glass during firing. In this case, the amount of the alkaline earth metal oxide in the glass in the form of a fired body is greater than the amount of the alkaline earth metal oxide in the glass before firing.

The above leads to the assumption that a reduction in dielectric loss requires specifying an alkaline earth metal oxide contained as a glass component of a fired body obtained by firing.

Based on the above matter, the present disclosure aims to provide a low-temperature fired ceramic with a small dielectric loss.

The low-temperature fired ceramic of the present disclosure contains a fired glass component and one or more oxides of ceramic crystalline components, wherein the fired glass component contains B₂O₃, SiO₂, and an alkaline earth metal oxide and excluding Li₂O, and a percentage of the alkaline earth metal oxide in the fired glass component is 10 mol % or less.

The electronic component of the present disclosure contains the low-temperature fired ceramic of the present disclosure.

The present disclosure can provide a low-temperature fired ceramic with a small dielectric loss.

### BRIEF DESCRIPTION OF THE DRAWINGS

FIG. 1 is a schematic cross-sectional view of an example of a multilayer ceramic electronic component as an electronic component of the present disclosure.

FIG. 2 is a schematic cross-sectional view of a multilayer green sheet (in an unfired state) produced during the production process of the multilayer ceramic electronic component in FIG. 1.

### DESCRIPTION OF THE PREFERRED EMBODIMENTS

The low-temperature fired ceramic and the electronic component of the present disclosure are described below. The present disclosure is not limited to the following preferred embodiments and may be suitably modified without departing from the gist of the present disclosure. Combinations of two or more preferred features described in the following preferred features are also within the scope of the present disclosure.

The low-temperature fired ceramic of the present disclosure is a fired body obtained by firing a low-temperature co-fired ceramic (LTCC) material, which is a glass ceramic material that can be sintered at a firing temperature of 1000° C. or lower.

The low-temperature fired ceramic of the present disclosure contains a fired glass component and one or more oxides of ceramic crystalline components.

The fired glass component contains B₂O₃, SiO₂, and an alkaline earth metal oxide. The percentage of the alkaline earth metal oxide in the fired glass component is 10 mol % or less.

In the low-temperature fired ceramic of the present disclosure, the percentage of the alkaline earth metal oxide in the fired glass component is specified to be low, which results in a low-temperature fired ceramic with a small dielectric loss.

Among the components of the low-temperature fired ceramic, the fired glass component has a large dielectric loss, and the oxides of the ceramic crystalline components have a small dielectric loss. The dielectric loss of the fired glass component is dominant over the dielectric loss of the low-temperature fired ceramic, so that it is important to reduce the dielectric loss of the fired glass component. Thus, the percentage of the alkaline earth metal oxide in the fired glass component is specified to be low, so that the dielectric loss of the low-temperature fired ceramic is reduced.

The low-temperature co-fired ceramic (LTCC) material contains an alkaline earth metal oxide in a glass component before firing. The alkaline earth metal oxide precipitates from the glass by firing, which reduces the percentage of the alkaline earth metal oxide in the fired glass component. Precipitation of the alkaline earth metal oxide from the glass by firing results in a low-temperature fired ceramic with a small dielectric loss.

The percentage of the alkaline earth metal oxide in the fired glass component is preferably 8.0 mol % or less, more preferably 6.0 mol % or less. The percentage of the alkaline earth metal oxide in the fired glass component may be 0.1 mol % or more.

The percentage of the alkaline earth metal oxide in the fired glass component can be obtained by measuring the low-temperature fired ceramic (fired body) by powder X-ray diffraction (XRD measurement) at a low scanning rate of 0.2 deg/min and determining the composition of the glass components by Rietveld analysis.

When measuring a fired body sample of a commercial product, a glass area of an exfoliated sample is identified by STEM and electron diffraction, and the glass area is measured by wavelength dispersive X-ray analysis (WDS), whereby the composition of the glass components can be determined. The crystal phase that is present can be identified by electron diffraction.

The alkaline earth metal oxide in the fired glass component may be MgO, Cao, Sro, or Bao, preferably BaO.

Preferably, the fired glass component further contains TiO₂.

The presence of Bao and TiO in the composition of the fired glass component can particularly increase the permittivity and reduce the dielectric loss.

Preferably, the fired glass component does not contains Al₂O₃.

In Patent Literature 1, Al₂O₃ is an essential component of a glass composition, in addition to B₂O₃ and SiO₂. When using a glass composition as a glass ceramic material that can be fired at a low temperature, the glass composition is mixed with a ceramic and fired.

To increase the permittivity of the glass ceramic, a ceramic having a high permittivity with low temperature-dependence, such as Ba₂Ti₉O₂₀, is preferably used. Yet, such a ceramic cannot be used when the glass contains Al₂O₃ as a component because Al₂O₃ reacts with a ceramic such as Ba₂Ti₉O₂₀ and decomposes.

Based on the above, preferably, the fired glass component does not contain Al₂O₃.

Preferably, the fired glass component does not contain an alkali metal oxide. A low-temperature fired ceramic with a small dielectric loss can be obtained because the fired glass component does not contain an alkali metal oxide. When the fired glass component contains an alkali metal oxide, the percentage of the alkali metal oxide in the fired glass component is preferably 0.1 mol % or less.

Based on the above, preferably, the fired glass component contains B₂O₃, SiO₂, BaO, and TiO₂ and does not contain other oxides.

Preferred percentages of B₂O₃, SiO₂, Bao, and TiO₂ as the fired glass component are as follows:
B₂O₃: 21 mol % to 65 mol %
SiO₂: 24 mol % to 62 mol %
BaO: 0.1 mol % to 10 mol %
TiO₂: 0.1 mol % to 10 mol %

Preferably, the oxides of the ceramic crystalline components include Ba₂Ti₉O₂₀. A low-temperature fired ceramic with a high permittivity with low temperature-dependence can be obtained because Ba₂Ti₉O₂₀ is included.

The percentage of Ba₂Ti₉O₂₀ in the low-temperature fired ceramic is preferably 55 wt % or more, more preferably 60 wt % or more, still more preferably 70 wt % or more, particularly preferably 80 wt % or more.

The oxides of the ceramic crystalline components include Ba₂Ti₉O₂₀ and may further include at least one selected from the group consisting of BaTi (BO₃)₂, BaTi₅O₁₁, Ba₂TiSi₂O₈, and TiO₂.

Among the oxides of the ceramic crystalline components, the oxides of the ceramic crystalline components other than TiO₂ have a characteristic that the permittivity increases with an increase in temperature. In contrast, TiO₂ has a characteristic that the permittivity decreases with an increase in temperature. Thus, the characteristic of the low-temperature fired ceramic can be adjusted such that the permittivity does not change with temperature by adding a predetermined amount of TiO₂ to the oxides of the ceramic crystalline components other than TiO₂. Thus, TiO₂ can be used to adjust the temperature dependence that is a characteristic of the low-temperature fired ceramic. TiO₂ as the oxide of the ceramic crystalline component can be distinguished from TiO₂ as the fired glass component.

Preferred percentages of BaTi (BO₃)₂, BaTi₅O₁₁, Ba₂TiSi₂O₈, and TiO₂ as the oxides of the ceramic crystalline components of the low-temperature fired ceramic are as follows:
BaTi (BO₃)₂: 0 wt % to 20 wt %
BaTi₅O₁₁: 0 wt % to 20 wt %
Ba₂TiSi₂O₈: 0 wt % to 20 wt %
TiO₂: 0.1 wt % to 20 wt %

The percentages of the fired glass component and the oxides of the ceramic crystalline components in the low-temperature fired ceramic are not limited. The percentage of the fired glass component in the low-temperature fired ceramic can be 2.0 wt % to 30.0 wt %, and the total percentage of the oxides of the ceramic crystalline components can be 70.0 wt % to 98.0 wt %.

The relative density of the low-temperature fired ceramic is preferably 90% or more, more preferably 95% or more. The term “relative density” refers to the value obtained by dividing the density measured by the Archimedes method by the true density. A reduction in insulation may occur at a relative density of less than 90%. Empirically, a reduction in insulation does not occur at a relative density of 95% or more.

The relative permittivity of the low-temperature fired ceramic is preferably 15 or more, and the Q-factor as the reciprocal of dielectric loss is preferably 1000 or more. The dielectric loss is preferably 0.001 or less.

The relative permittivity and the dielectric loss of the low-temperature fired ceramic can be measured as the relative permittivity and the dielectric loss at 3 GHZ, respectively, by the perturbation method.

The electronic component of the present disclosure includes the low-temperature fired ceramic of the present disclosure.

Examples of the electronic component of the present disclosure include a laminate including multiple low-temperature fired ceramic layers containing the low-temperature fired ceramic of the present disclosure, and a multilayer ceramic electronic component including a multilayer ceramic substrate including the laminate and a chip component mounted on the ceramic substrate.

The electronic component of the present disclosure includes the low-temperature fired ceramic layers containing the low-temperature fired ceramic of the present disclosure and thus has a high permittivity and a small dielectric loss.

The laminate including multiple low-temperature fired ceramic layers containing the low-temperature fired ceramic of the present disclosure can be used as a ceramic multilayer substrate for communication or a multilayer dielectric filter, for example.

The electronic component of the present disclosure has a high permittivity, a small dielectric loss, and a high Q-factor and is thus suitable as an electronic component that is used particularly in the millimeter wave band.

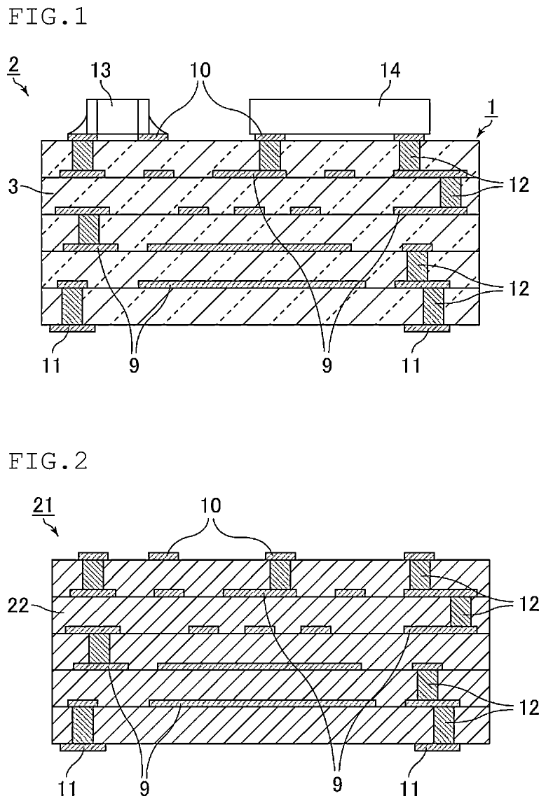

FIG. 1 is a schematic cross-sectional view of an example of a multilayer ceramic electronic component as the electronic component of the present disclosure. As shown in FIG. 1, an electronic component 2 includes a laminate 1 including a stack of multiple low-temperature fired ceramic layers 3 (five layers in FIG. 1) and chip components 13 and 14 mounted on the laminate 1. The laminate 1 is also a multilayer ceramic substrate.

The low-temperature fired ceramic layers 3 are a fired body containing the low-temperature fired ceramic of the present disclosure. Thus, the laminate 1 including a stack of the multiple low-temperature fired ceramic layers 3, and the electronic component 2 including a multilayer ceramic substrate including the laminate 1 and the chip components 13 and 14 mounted the multilayer ceramic substrate (the laminate 1) are both the electronic components of the present disclosure. The multiple low-temperature fired ceramic layers 3 may each have the same composition or a different composition, but preferably the same.

The laminate 1 may further include conductive layers. For example, the conductive layers may define passive elements such as capacitors and inductors or may define connection wiring for electric connection between elements. Such conductive layers include conductive layers 9, 10, and 11 and via hole conductive layers 12 shown in FIG. 1.

Preferably, the conductive layers 9, 10, and 11 and the via hole conductive layers 12 each contain Ag or Cu as a main component. Use of such a low-resistance metal prevents the occurrence of signal propagation delay associated with an increase in frequency of electric signals. Since the low-temperature fired ceramic layers 3 are a fired body obtained by firing a low-temperature co-fired ceramic (LTCC) material, the low-temperature fired ceramic layers 3 can be formed by co-firing with Ag and Cu.

Specifically, the electronic component of the present disclosure preferably includes Cu wiring. Preferably, the electronic component includes Cu wiring formed by co-firing of a low-temperature co-fired ceramic (LTCC) material with Cu.

The conductive layers 9 are inside the laminate 1. Specifically, each conductive layer 9 is at an interface between the low-temperature fired ceramic layers 3.

The conductive layers 10 are on one of main surfaces of the laminate 1.

The conductive layers 11 are on the other main surface of the laminate 1.

Each via hole conductive layer 12 is disposed to penetrate the low-temperature fired ceramic layer 3 and plays a role in electrically connecting the conductive layers 9 at different levels to each other, electrically connecting the conductive layers 9 and 10 to each other, and electrically connecting the conductive layers 9 and 11 to each other.

The laminate 1 is produced as follows, for example.

### (A) Preparation of Glass Composition

B₂O₃, SiO₂, and an alkaline earth metal oxide are mixed at a predetermined ratio to prepare a glass composition. BaO is preferably used as the alkaline earth metal oxide, and TiO₂ is preferably added to the glass composition.

### (B) Preparation of Glass Powder

The glass composition is melted, and the resulting melt is quenched to produce cullet. The cullet is coarsely ground and is further ground in a ball mill or the like to prepare a glass powder having a predetermined particle size.

### (C) Preparation of Low-Temperature Co-fired Ceramic (LTCC) Material

The glass powder is mixed with an oxide of a ceramic crystalline component to prepare a low-temperature co-fired ceramic material. Ba₂Ti₉O₂₀ is preferably used as the oxide of the ceramic crystalline component.

The percentage of the glass powder in the low-temperature co-fired ceramic (LTCC) material is preferably 20 wt % to 40 wt %.

### (D) Production of Green Sheets

A low-temperature co-fired ceramic material is mixed with a binder, a plasticizer, etc., to prepare a ceramic slurry. Then, the ceramic slurry is applied to a base film (e.g., a polyethylene terephthalate (PET) film) and then dried to produce a green sheet.

### (E) Production of Multilayer Green Sheet

The green sheets are stacked to produce a multilayer green sheet (in an unfired state). FIG. 2 is a schematic cross-sectional view of the multilayer green sheet (in an unfired state) produced during the production process of the multilayer ceramic electronic component in FIG. 1. As shown in FIG. 2, a multilayer green sheet 21 includes a stack of multiple green sheets 22 (five sheets in FIG. 2). The green sheets 22 are converted into the low-temperature fired ceramic layers 3 after firing. The multilayer green sheet 21 may include conductive layers including the conductive layers 9, 10, and 11 and the via hole conductive layers 12. The conductive layers can be formed by a method such as screen printing or photolithography using a conductive paste containing Ag or Cu.

### (F) Firing of Multilayer Green Sheet

The multilayer green sheet 21 is fired. As a result, the laminate 1 shown in FIG. 1 is obtained.

The firing temperature of the multilayer green sheet 21 is not limited as long as it is a temperature at which the low-temperature co-fired ceramic material of the green sheets 22 can be sintered. For example, the firing temperature may be 1000° C. or lower.

The firing atmosphere of the multilayer green sheet 21 is not limited. Yet, when a material resistant to oxidation, such as Ag, is used to form the conductive layers 9, 10, and 11 and the via hole conductive layers 12, an air atmosphere is preferred; while when a material prone to oxidation, such as Cu, is used, a hypoxic atmosphere such as a nitrogen atmosphere is preferred. The firing atmosphere of the multilayer green sheet 21 may be a reducing atmosphere.

The multilayer green sheet 21 may be fired in a state of being sandwiched by restraint green sheets. The restraint green sheets contain, as a main component, an inorganic material (e.g., Al₂O₃) that is not substantially sintered at a sintering temperature of the low-temperature co-fired ceramic material of the green sheets 22. Thus, the restraint green sheets do not shrink at the time of firing of the multilayer green sheet 21, and act to reduce or prevent shrinkage in the main surface direction of the multilayer green sheet 21. This improves the dimensional accuracy of the resulting laminate 1 (particularly, the conductive layers 9, 10, and 11 and the via hole conductive layers 12).

The chip components 13 and 14 may be mounted on the laminate 1 while being electrically connected to the conductive layers 10. Thus, the electronic component 2 including the laminate 1 is configured.

Examples of the chip components 13 and 14 include LC filters, capacitors, and inductors.

The electronic component 2 may be mounted on a mounting board (e.g., motherboard) in an electrically connected manner via the conductive layers 11.

### EXAMPLES

The following describes examples that more specifically disclose the low-temperature fired ceramic and the electronic component of the present disclosure. The present disclosure is not limited to these examples.

### (A) Preparation of Glass

Glass powders G1 to G4 (all in the powder form) having compositions shown in Table 1 were produced by the following method. First, powdered glass raw materials were mixed to obtain a glass composition. The glass composition was placed in a crucible made of Pt and melted in an air atmosphere at 1600° C. for 30 minutes or longer. Subsequently, the resulting melt was quenched to obtain cullet. Carbonate (BaCO₃) was used as a raw material of an alkaline earth metal oxide (BaO). Although carbonate (BaCO₃) is converted into an alkaline earth metal oxide (BaO) by firing, Table 1 shows the amounts in terms of BaO.

The cullet was coarsely ground. Then, the ground cullet was placed in a container together with ethanol and PSZ balls (diameter: 5 mm) and mixed in a ball mill. When mixing in the ball mill, the grinding time was adjusted, whereby a glass powder having a median particle size of 1.0 μm was obtained. Here, the term “median particle size” refers to the median particle size D50 determined by the laser diffraction scattering method.

### (B) Production of Green Sheet

Next, each glass powder and oxides of ceramic crystalline components (median particle size: 1.0 μm) were placed in ethanol and mixed in a ball mill according to the composition shown in Table 2. The resulting mixture was further mixed with a binder solution dissolved in an organic solvent to obtain a slurry. The slurry was applied to a PET film using a doctor blade and dried at 40° C. to obtain a 50-micron-thick green sheet.

“LTCC materials before firing [wt %]” in Table 2 shows the percentages by weight of the glass powder and the oxides of the ceramic crystalline components, Ba₂Ti₉O₂₀ and TiO₂, in the green sheet.

### (C) Production of Evaluation Samples and Evaluation

To prepare samples for evaluation of sinterability, the green sheet was cut into 50-mm square pieces, and 20 of these pieces were stacked, placed in a mold, and compression-bonded using a pressing machine. The compression-bonded body was fired in an air atmosphere at 900° C. for 60 minutes. After firing, the density was measured by the Archimedes method, and the relative permittivity at 3 GHZ and Q-factor (reciprocal of dielectric loss) were measured by the perturbation method. The measurement conditions were as follows.

### Measurement Device and Measurement Conditions

Network analyzer: 8757D available from Keysight Technologies
Signal generator: Keysight 83751 synthesized sweeper available from Keysight Technologies
Resonator: scratch-built jig (resonant frequency: 3 GHz)

Prior to the measurement, the network analyzer and the signal generator were connected to each other to measure cable loss. The resonator was calibrated using a standard substrate (made of quartz; relative permittivity: 3.73; Q-factor: 9091 at 3 GHz; thickness: 0.636 mm).

The fired body was ground, and the true density of the powder was measured. The density measured by the Archimedes method was divided by the true density. The resulting value was regarded as the relative density (%).

To further analyze the composition of the fired body, the fired body was measured by powder XRD at a low scanning rate of (0.2 deg/min), and the percentages of the fired glass component of the fired body and the composition of the fired glass component were determined by Rietveld analysis. The composition was determined based on the assumption that the total amount of oxides of the elements would be the same before and after firing.

The compositions of the oxides of the ceramic crystalline components of the fired body were also determined.

Table 2 and Table 3 show the results.

TABLE 1

| Glass | Glass composition [mol %] | | | | Glass composition [wt %] | | | |
|---|---|---|---|---|---|---|---|---|
| powder No. | BaO | TiO₂ | B₂O₃ | SiO₂ | BaO | TiO₂ | B₂O₃ | SiO₂ |
| G1 | 10.0 | 10.0 | 55.0 | 25.0 | 20.0 | 10.4 | 50.0 | 19.6 |
| G2 | 20.0 | 15.0 | 40.0 | 25.0 | 35.9 | 14.0 | 32.6 | 17.6 |
| G3 | 25.0 | 25.0 | 25.0 | 25.0 | 42.3 | 22.0 | 19.2 | 16.6 |
| G4 | 30.0 | 25.0 | 20.0 | 25.0 | 48.5 | 21.0 | 14.7 | 15.8 |

TABLE 2

| | Glass | LTCC materials before firing [wt %] | | | Fired low-temperature fired ceramic [wt %] | | | | | Relative |
|---|---|---|---|---|---|---|---|---|---|---|
| Sample | powder | Glass | | | Fired glass | | | | | density |
| No. | No. | powder | Ba₂Ti₉O₂₀ | TiO₂ | component | Ba₂Ti₉O₂₀ | BaTi(BO₃)₂ | Ba₂TiSi₂O₈ | TiO₂ | [%] |
| S1 | G1 | 40.0 | 60.0 | 0.0 | 36.2 | 60.0 | 0.0 | 0.0 | 3.8 | 96 |
| S2 | G2 | 40.0 | 60.0 | 0.0 | 17.8 | 60.0 | 12.7 | 9.5 | 0.0 | 95 |
| S3 | G3 | 20.0 | 80.0 | 0.0 | 4.4 | 80.0 | 4.3 | 10.1 | 1.2 | 97 |
| S4 | G4 | 30.0 | 70.0 | 0.0 | 8.0 | 70.0 | 9.6 | 10.9 | 1.5 | 96 |
| S5 | G3 | 30.0 | 68.0 | 2.0 | 7.8 | 68.0 | 18.0 | 3.7 | 5.0 | 95 |

TABLE 3

| | Composition of fired glass | | | | Electrical characteristics | |
|---|---|---|---|---|---|---|
| Sample | components [mol %] | | | | (measured at 3 GHz) | |
| No. | BaO | TiO₂ | B₂O₃ | SiO₂ | Relative permittivity | Q-factor |
| S1 | 11.0 | 1.1 | 60.4 | 27.5 | 28 | 450 |
| S2 | 5.7 | 3.8 | 58.5 | 32.1 | 31 | 2100 |
| S3 | 1.8 | 8.8 | 64.9 | 24.6 | 33 | 3800 |
| S4 | 21.3 | 7.3 | 33.3 | 38.0 | 32 | 180 |
| S5 | 7.9 | 8.5 | 21.2 | 32.7 | 36 | 1700 |

Each of the fired low-temperature fired ceramics of sample Nos. S2, S3 and S5 in which the percentage of the alkaline earth metal oxide (i.e., the percentage of BaO shown in Table 3) as the fired glass component was 10 mol % or less corresponds to the low-temperature fired ceramics of the present disclosure.

The Q-factor was high in each sample, indicating a low-temperature fired ceramic with a small dielectric loss. The permittivity was high in each sample.

The relative density was as high as 95% or more in each sample, preventing a reduction in insulation.

The present description discloses the following.

Disclosure (1) relates to a low-temperature fired ceramic containing: a fired glass component that contains B₂O₃, SiO₂, and an alkaline earth metal oxide and excluding Li₂O, and a percentage of the alkaline earth metal oxide in the fired glass component is 10 mol % or less; and one or more oxides of ceramic crystalline components.

Disclosure (2) relates to the low-temperature fired ceramic according to Disclosure (1), wherein the alkaline earth metal oxide in the fired glass component is BaO.

Disclosure (3) relates to the low-temperature fired ceramic according to Disclosure (1) or (2), wherein the fired glass component further contains TiO₂.

Disclosure (4) relates to the low-temperature fired ceramic according to any combination of Disclosure (1) to Disclosure (3), wherein the one or more oxides of the ceramic crystalline components include Ba₂Ti₉O₂₀.

Disclosure (5) relates to the low-temperature fired ceramic according to Disclosure (4), wherein a percentage of the Ba₂Ti₉O₂₀ in the low-temperature fired ceramic is 55 wt % or more.

Disclosure (6) relates to the low-temperature fired ceramic according to Disclosure (4) or (5), wherein the one or more oxides of the ceramic crystalline components further include at least one of BaTi (BO₃)₂, BaTi₅O₁₁, Ba₂TiSi₂O₈, and TiO₂.

Disclosure (7) relates to an electronic component including the low-temperature fired ceramic according to any combination of Disclosure (1) to Disclosure (6).

Disclosure (8) relates to the electronic component according to Disclosure (7), wherein the electronic component includes Cu wiring.

### REFERENCE SIGNS LIST

1 laminate
2 electronic component
3 low-temperature fired ceramic layer
9, 10, 11 conductive layer
12 via hole conductive layer
13, 14 chip component
21 multilayer green sheet
22 green sheet

1. A low-temperature fired ceramic comprising:
a fired glass component that contains B₂O₃, SiO₂, and an alkaline earth metal oxide and excluding Li₂O, and a percentage of the alkaline earth metal oxide in the fired glass component is 10 mol % or less; and
one or more oxides of ceramic crystalline components.

2. The low-temperature fired ceramic according to claim 1, wherein the percentage of the alkaline earth metal oxide in the fired glass component is 0.1 mol % to 8.0 mol %.

3. The low-temperature fired ceramic according to claim 1, wherein the alkaline earth metal oxide in the fired glass component includes at least one of MgO, Cao, Sro, and BaO.

4. The low-temperature fired ceramic according to claim 1, wherein the alkaline earth metal oxide in the fired glass component is BaO.

5. The low-temperature fired ceramic according to claim 4, wherein the fired glass component further contains TiO₂.

6. The low-temperature fired ceramic according to claim 5, wherein percentages of B₂O₃, SiO₂, Bao, and TiO₂ in the fired glass component are:
B₂O₃: 21 mol % to 65 mol %,
SiO₂: 24 mol % to 62 mol %,
BaO: 0.1 mol % to 10 mol %, and
TiO₂: 0.1 mol % to 10 mol %.

7. The low-temperature fired ceramic according to claim 1, wherein the fired glass component further contains TiO₂.

8. The low-temperature fired ceramic according to claim 1, wherein the fired glass component does not contain Al₂O₃.

9. The low-temperature fired ceramic according to claim 1, wherein the one or more oxides of the ceramic crystalline components include Ba₂Ti₉O₂₀.

10. The low-temperature fired ceramic according to claim 9, wherein a percentage of the Ba₂Ti₉O₂₀ in the low-temperature fired ceramic is 55 wt % or more.

11. The low-temperature fired ceramic according to claim 9, wherein the one or more oxides of the ceramic crystalline components further include at least one of BaTi (BO₃)₂, BaTi₅O₁₁, Ba₂TiSi₂O₈, and TiO₂.

12. The low-temperature fired ceramic according to claim 11, wherein percentages of BaTi (BO₃)₂, BaTi₅O₁₁, Ba₂TiSi₂O₈, and TiO₂ as the oxides of the ceramic crystalline components in the low-temperature fired ceramic are as follows:
BaTi (BO₃)₂: 0 wt % to 20 wt %,
BaTi₅O₁₁: 0 wt % to 20 wt %,
Ba₂TiSi₂O₈: 0 wt % to 20 wt %, and
TiO₂: 0.1 wt % to 20 wt %.

13. The low-temperature fired ceramic according to claim 1, wherein a percentage of the fired glass component in the low-temperature fired ceramic is 2.0 wt % to 30.0 wt %, and a total percentage of the oxides of the ceramic crystalline components is 70.0 wt % to 98.0 wt %.

14. The low-temperature fired ceramic according to claim 1, wherein a relative density of the low-temperature fired ceramic is 90% or more.

15. The low-temperature fired ceramic according to claim 1, wherein relative permittivity of the low-temperature fired ceramic is 15 or more, and a Q-factor as a reciprocal of dielectric loss is 1000 or more.

16. An electronic component comprising the low-temperature fired ceramic according to claim 1.

17. The electronic component according to claim 16, wherein the electronic component includes Cu wiring.
